(19) United States
(12) Patent Application Publication
(10) Pub. No.: US 2026/0366154 A1
(43) Pub. Date: Nov. 19, 2026

(54) Novel Aminoalkoxysilylamine Compound, Preparation Method Therefor, and Silicon-Containing Thin Film Deposition Composition Comprising Same

(71) Applicant: DNF Co., Ltd., Daedeok-gu, Daejeon (KR)

(72) Inventors: Sung Gi Kim, Daedeok-gu, Daejeon (KR); Seung Son, Daedeok-gu, Daejeon (KR); Yu Jin Cho, Daedeok-gu, Daejeon (KR); Jiho Ryu, Daedeok-gu, Daejeon (KR); Se Jin Jang, Daedeok-gu, Daejeon (KR); Joong Jin Park, Daedeok-gu, Daejeon (KR); Jun Hee Cho, Daedeok-gu, Daejeon (KR); Gun Joo Park, Daedeok-gu, Daejeon (KR)

(21) Appl. No.: 19/487,055

(22) PCT Filed: May 24, 2024
(86) PCT No.: PCT/KR2024/007061

§ 371 Date: Nov. 24, 2025

(30) Foreign Application Priority Data
May 25, 2023 (KR) 10-2023-0067834
May 23, 2024 (KR) 10-2024-0067176

(51) Int. Cl. C23C 16/455; C01B 33/12; C07F 7/18; C23C 16/40; C23C 16/505

(52) U.S. Cl. CPC C23C 16/45553; C01B 33/126; C07F 7/1888; C23C 16/40; C23C 16/45536; C23C 16/505

(57) ABSTRACT

A aminoalkoxysilylamine compound, a method therefor, a silicon-containing thin film deposition composition including the compound, and a method for manufacturing a silicon-containing thin film using the composition. The aminoalkoxysilylamine compound according to the present disclosure is thermally stable and has high volatility and reactivity, and thus is very useful for stably manufacturing a silicon-containing thin film having excellent properties in a wide temperature range.

### CROSS-REFERENCE TO RELATED APPLICATIONS

This application is the United States national phase of International Patent Application No. PCT/KR2024/007061 filed May 24, 2024, and claims priority to Korean Patent Application No. 10-2023-0067834 filed May 25, 2023, and Korean Patent Application No. 10-2024-0067176 filed May 23, 2024, the disclosures of which are hereby incorporated by reference in their entireties.

### BACKGROUND

### Technical Field

The present disclosure relates to a novel aminoalkoxysilylamine compound, a method for preparing the same, a composition for depositing a silicon-containing thin film including the same, and a method for manufacturing a silicon-containing thin film using the same.

### Technical Considerations

A silicon-containing thin film is manufactured into various forms of thin films such as a silicon film, a silicon oxide film, a silicon nitride film, a silicon carbonitride film, and a silicon oxynitride film by various deposition processes in the semiconductor field, and recently, a polycrystalline silicon thin film has been used in a thin film transistor (TFT), a solar battery, and the like and its application fields are becoming increasingly diverse.

A representative technology known for the manufacture of a silicon-containing thin film includes chemical vapor deposition (MOCVD) in which a silicon precursor in the form of mixed gas reacts with a reaction gas to form a film on a substrate surface, or directly reacts on the surface to form a film and atomic layer deposition (ALD) in which a silicon precursor in a gas form is physically or chemically adsorbed on a substrate surface, and then forms a film by subsequently adding reaction gas, and various thin film manufacturing technologies using the technologies such as low pressure chemical vapor deposition (LPCVD), and plasma-enhanced chemical vapor deposition (PECVD) and plasma-enhanced atomic layer deposition (PEALD) which allow deposition at a low temperature using plasma, are applied to next generation semiconductor and display device manufacturing processes and used in ultrathin film deposition having uniform and excellent properties in ultrafine pattern formation and a nano-thickness.

A precursor used for forming a silicon-containing thin film is representatively compounds in the form of silane, silane chloride, aminosilane, and alkoxysilane, and as a specific example, compounds in the form of silane chloride such as dichlorosilane (SiH2Cl2) and hexachlorodisilane (Cl3SiSiCl3), trisilylamine (N(SiH3)3), bis-diethylaminosilane (H2Si(N(CH2CH3)2)2), di-isopropylaminosilane (H3SiN (i-C3H7)2), and the like are included, which are being used in semiconductor manufacture and display manufacture mass production processes.

However, due to miniaturization and an increased aspect ratio of elements resulting from ultrahigh integration of the elements, and diversification of element materials, a technology for forming an ultrafine thin film having a uniform small thickness and excellent electrical properties at a desired low temperature is required, and thus, a high temperature process at 600 °C or higher using a conventional silicon precursor, step coverage, etching properties, and the physical and electrical properties of the thin film are becoming a problem, and thus, development of a novel and improved silicon precursor is demanded. Related art may be found in Monatshefte fuer Chemie (1968), 99(4), 1372-5.

### SUMMARY

An object of the present disclosure is to provide a novel aminoalkoxysilylamine compound.

Specifically, an object of the present disclosure is to provide an aminoalkoxysilylamine compound which is useful as a precursor forming a silicon-containing thin film and is thermally stable and highly volatile.

Specifically, an object of the present disclosure is to provide a novel aminoalkoxysilylamine compound which may form a stable silicon-containing thin film with excellent reactivity in a broad temperature range.

Another object of the present disclosure is to provide a method for preparing the aminoalkoxysilylamine compound.

Another object of the present disclosure is to provide a composition for depositing a silicon-containing thin film including the aminoalkoxysilylamine compound according to an exemplary embodiment of the present disclosure.

Still another object of the present disclosure is to provide a method for forming a silicon-containing thin film having excellent characteristics using a composition for depositing a silicon-containing thin film including the aminoalkoxysilylamine compound.

In one non-limiting aspect, an aminoalkoxysilylamine compound represented by the following Chemical Formula 1 is provided:

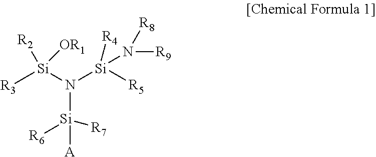

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl;
with the proviso that cases in which A is OR₁₂, R₁, R₈, R₉, and R₁₂ are all ethyl, and R₂ to R₇ are all methyl are excluded.

In the compound of Chemical Formula 1 according to an exemplary embodiment, R₁ may be C1-C3 alkyl; R₂, R₃, R₆, and R₇ may be independently of one another hydrogen, C1-C3 alkyl, or C1-C3 alkoxy; R₄, R₅, and R₈ may be independently of one another hydrogen or C1-C3 alkyl; R₉ may be C1-C3 alkyl; A may be NR₁₀R₁₁ or OR₁₂; R₁₀ may be hydrogen or C1-C3 alkyl; and R₁₁ and R₁₂ may be independently of each other C1-C5 alkyl.

The compound according to an exemplary embodiment may be a compound represented by the following Chemical Formula 2:

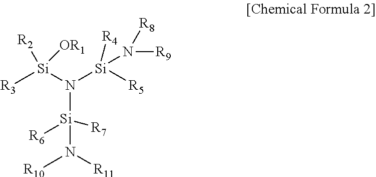

wherein
R₁ is C1-C5 alkyl;
R₂, R₃, R₆, and R₇ are independently of one another hydrogen, C1-C5 alkyl, or C1-C5 alkoxy;
R₄, R₅, R₈, and R₁₀ are independently of one another hydrogen or C1-C5 alkyl; and
R₉ and R₁₁ are C1-C5 alkyl.

In the compound of Chemical Formula 2 according to an exemplary embodiment, R₁ may be C1-C3 alkyl; R₂, R₃, R₆, and R₇ may be independently of one another hydrogen, C1-C3 alkyl, or C1-C3 alkoxy; R₄, R₅, R₈, and R₁₀ may be independently of one another hydrogen or C1-C3 alkyl; and R₇ and R₁₁ may be C1-C3 alkyl.

The compound according to an exemplary embodiment may be a compound represented by the following Chemical Formula 3:

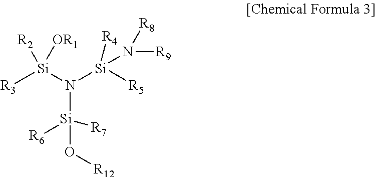

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl; and
R₉ and R₁₂ are independently of each other C1-C5 alkyl;
with the proviso that cases in which R₁, R₈, R₉, and R₁₂ are all ethyl and R₂ to R₇ are all methyl are excluded.

In the compound according to an exemplary embodiment, R₁ may be C1-C3 alkyl; R₂, R₃, R₆, and R₇ may be independently of one another hydrogen, C1-C3 alkyl, or C1-C3 alkoxy; R₄, R₅, and R₈ may be independently of one another hydrogen or C1-C3 alkyl; and R₉ and R₁₂ may be independently of one another C1-C3 alkyl.

The compound according to an exemplary embodiment may be at least one selected from the following structures:

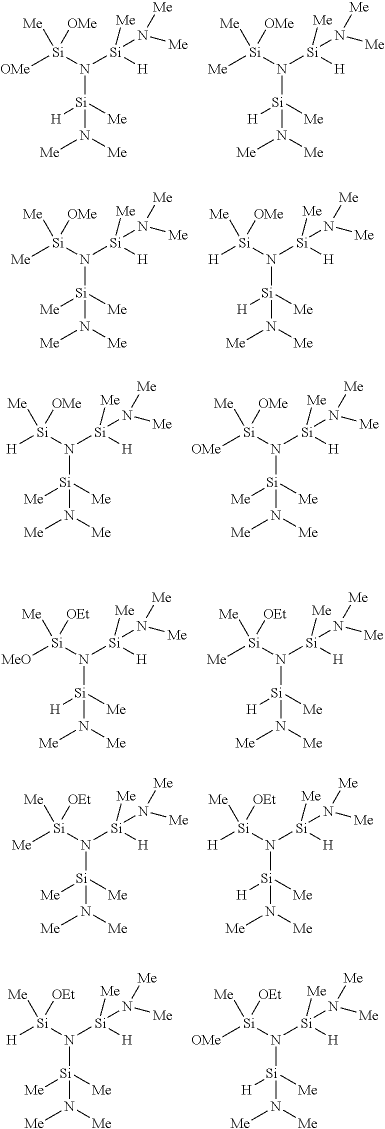

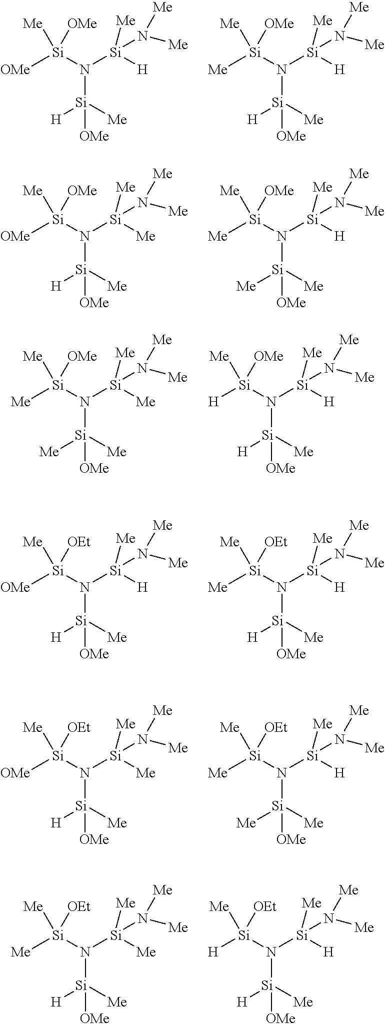

In another non-limiting aspect, a method for preparing an aminoalkoxysilylamine compound of the following Chemical Formula 1 includes: reacting (C1-C5)alkyllithium, a compound of the following Chemical Formula 4, and a compound of the following Chemical Formula 5 to prepare an aminoalkoxysilylamine compound of the following Chemical Formula 1:

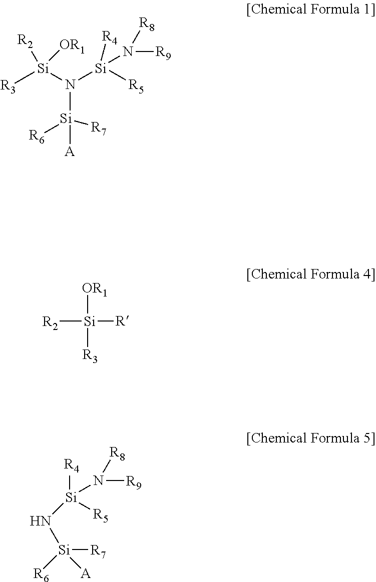

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
R′ is C1-C5 alkoxy or halogen;
A is NR₁₀R₁₁ or OR₁₂;
R₁₀ is hydrogen or C1-C5 alkyl; and
R₁₁ and R₁₂ are independently of each other C1-C5 alkyl;
with the proviso that cases in which A is OR₁₂, R₁, R₈, R₉, and R₁₂ are all ethyl and R₂ to R₇ are all methyl are excluded.

According to an exemplary embodiment, the method for preparing an aminoalkoxysilylamine compound of Chemical Formula 1 includes, when R′ is halogen in Chemical Formula 4, reacting a compound of the following Chemical Formula 6 and a halogen source to prepare the compound of Chemical Formula 4:

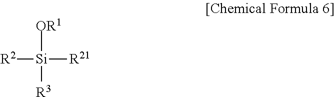

wherein
R₁ is C1-C5 alkyl;
R₂ and R₃ are independently of each other hydrogen, C1-C5 alkyl, or C1-C5 alkoxy; and
R₂₁ is C1-C5 alkoxy.

In another non-limiting aspect, a composition for depositing a silicon-containing thin film includes a compound represented by the following Chemical Formula 11:

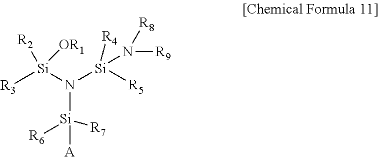

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl.

In still another non-limiting aspect, a method for manufacturing a silicon-containing thin film using a compound represented by the following Chemical Formula 11 is provided:

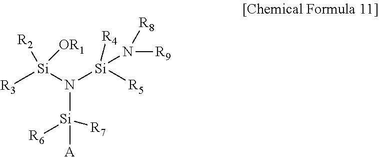

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl.

### Advantageous Effects

The aminoalkoxysilylamine compound according to the present disclosure is a novel compound, and may be provided as a precursor of a silicon-containing thin film which is thermally stable and highly volatile to form a silicon-containing thin film having excellent characteristics.

In addition, the aminoalkoxysilylamine compound according to the present disclosure may have excellent reactivity in a broad temperature range when a silicon-containing thin film is manufactured using the compound.

In addition, the method for preparing an aminoalkoxysilylamine compound according to an exemplary embodiment of the present disclosure may produce the aminoalkoxysilylamine compound efficiently in a high yield.

In addition, the composition for depositing a silicon-containing thin film according to an exemplary embodiment of the present disclosure includes the aminoalkoxysilylamine compound according to an exemplary embodiment of the present disclosure, thereby manufacturing a high-quality silicon-containing thin film.

### BRIEF DESCRIPTION OF THE DRAWINGS

FIG. 1 is a thermogravimetric analysis (TGA) graph of the aminoalkoxysilylamine compound prepared in Example 3.

FIG. 2 is a differential scanning calorimetry (DSC) graph of the aminoalkoxysilylamine compound prepared in Example 3.

FIG. 3 is a spectrum resulting from analysis of the silicon oxide thin film manufactured in Example 4 using an infrared spectrometer.

FIG. 4 is a graph showing a thin film thickness deposited per deposition cycle depending on a substrate temperature of Example 4, Comparative Example 1, and Comparative Example 2 by ellipsometry analysis.

FIG. 5 is a drawing showing results of confirming step coverage of a silicon oxide thin film deposited at a substrate temperature of 200 °C of Example 4.

FIG. 6 is a drawing showing results of confirming step coverage of a silicon oxide thin film deposited at a substrate temperature of 400 °C of Example 4.

### DETAILED DESCRIPTION

Hereinafter, the present disclosure will be described in detail. Technical terms and scientific terms used in the present specification have the general meaning understood by those skilled in the art to which the present disclosure pertains unless otherwise defined, and a description for the known function and configuration obscuring the present disclosure will be omitted in the following description.

The term “C_{A}-C_{B}” in the present specification refers to “having A or more and B or fewer carbon atoms”, and the term “A to B” refers to “A or more and B or less”.

The term “alkyl” of the present specification is a monovalent substituent and includes both linear or branched forms.

The alkyl may have 1 to 5 carbon atoms, specifically 1 to 3 carbon atoms.

The alkyl includes, as an example, methyl, ethyl, n-propyl, i-propyl, n-butyl, i-butyl, t-butyl, pentyl, and the like, but is not limited thereto.

The term “alkoxy” of the present specification is a —O-alkyl radical in which “alkyl” is as defined above. A specific example thereof includes methoxy, ethoxy, isopropoxy, butoxy, isobutoxy, t-butoxy, and the like, but is not limited thereto.

The term “halogen” of the present specification refers to a Group 17 element, and may be any one selected from F, Cl, Br, and I.

In addition, the term “comprise” in the present specification is an open-ended description having a meaning equivalent to the term such as “is/are provided”, “contain”, “have”, or “is/are characterized”, and does not exclude elements, materials, or processes which are not further listed.

In addition, the singular form used in the present specification may be intended to also include a plural form, unless otherwise indicated in the context.

The term “aminoalkoxysilylamine compound” of the present specification may be represented by Chemical Formula 1, and has the same meaning as the expression of “precursor of a silicon-containing thin film”.

The term “thermal stability” of the present specification may refer to physical properties which are not changed even during a continuous heating process or a high-temperature process, and specifically, refers to not causing a structural change even when exposed to the harsh conditions described above for a long time.

The term “silicon-containing thin film having excellent characteristics” of the present specification refers to a high-quality silicon-containing thin film having a high silicon content, excellent thermal stability, and excellent durability.

In the present specification, “normal temperature” may refer to a temperature in a state without artificial temperature adjustment, and, for example, the normal temperature may be 20 °C to 40 °C, 20 °C to 30 °C, or 23 °C to 26 °C.

The present disclosure provides a novel aminoalkoxysilylamine compound which is useful as a precursor for manufacturing a silicon-containing thin film, and the aminoalkoxysilylamine compound of the present disclosure is represented by the following Chemical Formula 1:

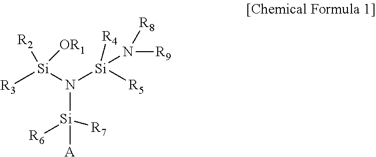

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl;
with the proviso that cases in which A is OR₁₂, R₁, R₈, R₉, and R₁₂ are all ethyl and R₂ to R₇ are all methyl are excluded.

The aminoalkoxysilylamine compound of the present disclosure has a structure in which at least one or more alkoxy functional groups and an amine functional group are introduced simultaneously to a silicon atom having a trisilylamine structure, has improved reactivity with lower activation energy due to the alkoxy functional group introduced to the silicon atom, and does not produce nonvolatile by-products, thereby easily forming a high-purity silicon-containing thin film with a high deposition rate.

The aminoalkoxysilylamine compound according to an exemplary embodiment of the present disclosure may be specifically represented by the aminosilylalkoxysilylamine compound.

In the aminoalkoxysilylamine compound according to a specific example, in Chemical Formula 1, R₁ may be C1-C3 alkyl; R₂, R₃, R₆, and R₇ may be independently of one another hydrogen, C1-C3 alkyl, or C1-C3 alkoxy; R₄, R₅, and R₈ may be independently of one another hydrogen or C1-C3 alkyl; R₉ may be C1-C3 alkyl; A may be NR₁₀R₁₁ or OR₁₂; R₁₀ may be hydrogen or C1-C3 alkyl; R₁₁ and R₁₂ may be independently of each other C1-C5 alkyl, and when A is OR₁₂, the case in which R₁, R₈, R₉, and R₁₂ are all ethyl and R₂ to R₇ are all methyl is excluded.

Specifically, the case in which A is OR₁₂ and R₁, R₈, R₉, and R₁₂ are all ethyl may be excluded from the aminoalkoxysilylamine compound according to an exemplary embodiment of the present disclosure.

As a specific example, the aminoalkoxysilylamine compound of the present disclosure may be a compound represented by the following Chemical Formula 2:

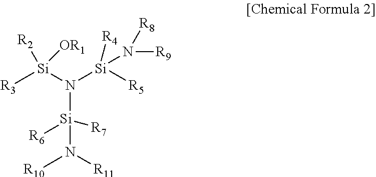

wherein
R₁ is C1-C5 alkyl;
R₂, R₃, R₆, and R₇ are independently of one another hydrogen, C1-C5 alkyl, or C1-C5 alkoxy;
R₄, R₅, R₈, and R₁₀ are independently of one another hydrogen or C1-C5 alkyl; and
R₉ and R₁₁ are C1-C5 alkyl.

In the compound of Chemical Formula 2 according to an exemplary embodiment, R₁ may be C1-C4 alkyl; R₂, R₃, R₆, and R₇ may be independently of one another hydrogen, C1-C4 alkyl, or C1-C4 alkoxy; R₄, R₅, R₈, and R₁₀ may be independently of one another hydrogen or C1-C4 alkyl; and R₇ and R₁₁ may be C1-C4 alkyl.

More specifically, R₁ may be C1-C3 alkyl; R₂, R₃, R₆, and R₇ may be independently of one another hydrogen, C1-C3 alkyl, or C1-C3 alkoxy; R₄, R₅, R₈, and R₁₀ may be independently of one another hydrogen or C1-C3 alkyl; and R₇ and R₁₁ may be C1-C3 alkyl.

As a specific example, the aminoalkoxysilylamine compound of the present disclosure may be a compound represented by the following Chemical Formula 3:

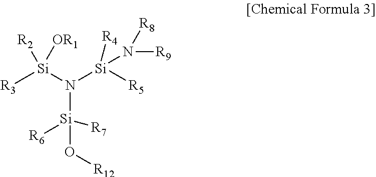

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl; and
R₉ and R₁₂ are independently of each other C1-C5 alkyl;
with the proviso that cases in which R₁, R₈, R₉, and R₁₂ are all ethyl and R₂ to R₇ are all methyl are excluded.

In the compound of Chemical Formula 3 according to a specific example, R₁ may be C1-C4 alkyl; R₂, R₃, R₆, and R₇ may be independently of one another hydrogen, C1-C4 alkyl, or C1-C4 alkoxy; R₄, R₅, and R₈ may be independently of one another hydrogen or C1-C4 alkyl; and R₇ and R₁₂ may be independently of each other C1-C4 alkyl; with the proviso that cases in which R₁, R₈, R₉, and R₁₂ are all ethyl and R₂ to R₇ are all methyl are excluded.

More specifically, R₁ may be C1-C3 alkyl; R₂, R₃, R₆, and R₇ may be independently of one another hydrogen, C1-C3 alkyl, or C1-C3 alkoxy; R₄, R₅, and R₈ may be independently of one another hydrogen or C1-C3 alkyl; and R₇ and R₁₂ may be independently of each other C1-C3 alkyl; with the proviso that cases in which R₁, R₈, R₉, and R₁₂ are all ethyl and R₂ to R₇ are all methyl are excluded.

The aminoalkoxysilylamine compound according to a specific example may be selected from the following compounds, but is not limited thereto:

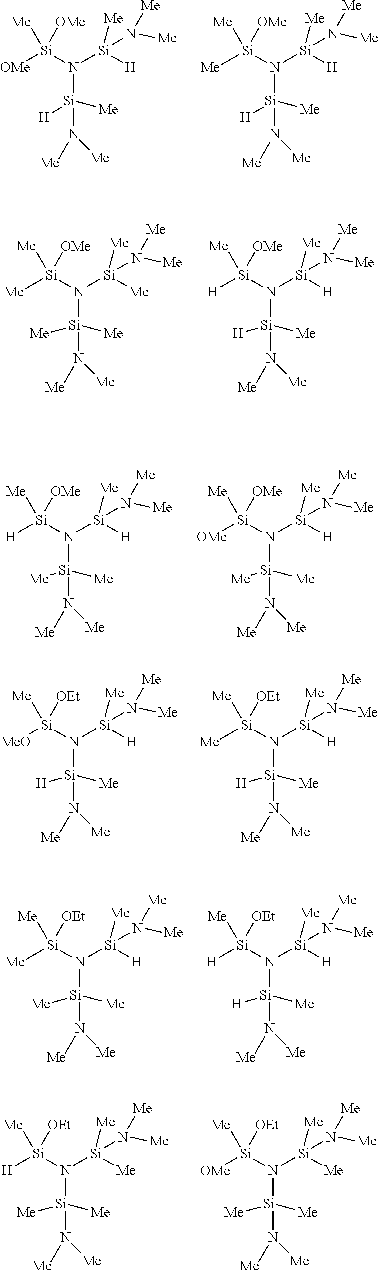

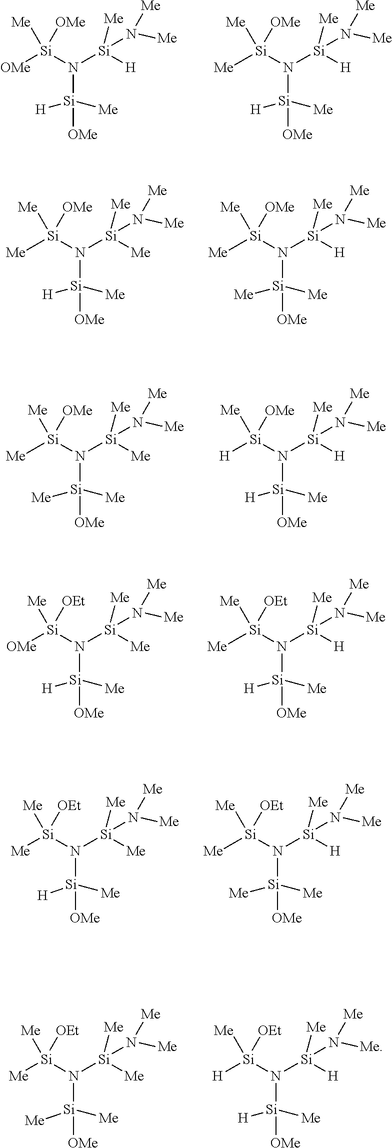

In addition, the present disclosure provides a method for preparing the aminoalkoxysilylamine compound.

s an exemplary embodiment, a method for preparing an aminoalkoxysilylamine compound of the following Chemical Formula 1 including: reacting (C1-C5)alkyllithium, a compound of the following Chemical Formula 4, and a compound of the following Chemical Formula 5 to prepare an aminoalkoxysilylamine compound of the following Chemical Formula 1 is provided:

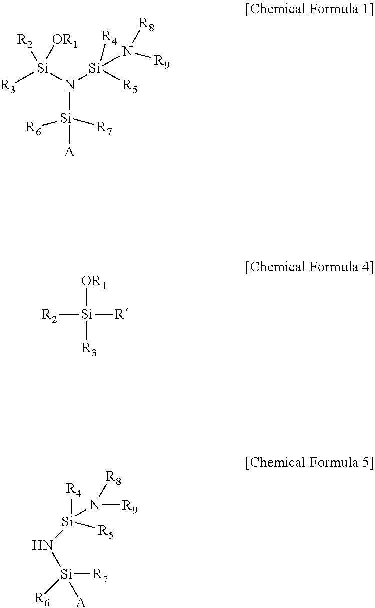

wherein R₁ is C1-C5 alkyl; R₂, R₃, R₆, and R₇ are independently of one another hydrogen, C1-C5 alkyl, or C1-C5 alkoxy; R₄, R₅, and R₈ are independently of one another hydrogen or C1-C5 alkyl; R₉ is C1-C5 alkyl; R′ is C1-C5 alkoxy or halogen; A is NR₁₀R₁₁ or OR₁₂; R₁₀ is hydrogen or C1-C5 alkyl; and R₁₁ and R₁₂ are independently of each other C1-C5 alkyl,
with the proviso that cases in which A is OR₁₂, R₁, R₈, R₉, and R₁₂ are all ethyl, and R₂ to R₇ are all methyl are excluded.

Specifically, the method for preparing the aminoalkoxysilylamine compound of Chemical Formula 1 may include: reacting (C1-C5)alkyllithium and the compound of Chemical Formula 5 to prepare a lithium salt; and reacting the lithium salt and the compound of Chemical Formula 4 to prepare the aminoalkoxysilylamine compound of Chemical Formula 1.

As a specific example, the lithium salt may be represented by the following Chemical Formula 9:

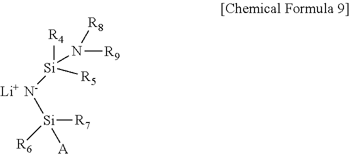

wherein the substituents are as defined in Chemical Formula 5 above.

In the method for preparing the aminoalkoxysilylamine compound of Chemical Formula 1 according to an exemplary embodiment of the present disclosure, when R′ is halogen in Chemical Formula 4, the compound of Chemical Formula 4 may be prepared by including reacting the compound of Chemical Formula 6 and a halogen source to prepare the compound of Chemical Formula 4:

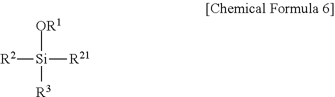

wherein R¹ is C1-C5 alkyl; R² and R³ are independently of each other hydrogen, C1-C5 alkyl, or C1-C5 alkoxy; R²¹ is C1-C5 alkoxy.

The halogen source according to an exemplary embodiment of the present disclosure may be any compound providing halogen which may undergo a substitution reaction with the functional group of Chemical Formula 6, but as an example, may be a compound of the following Chemical Formula 8.

More specifically, in Chemical Formula 4 according to an exemplary embodiment of the present disclosure, when R′ is halogen, the compound may be prepared by reacting the compound of Chemical Formula 4 and the compound of the following Chemical Formula 8 in the presence of a catalyst of the following Chemical Formula 7:

### [Chemical Formula 7]

MX¹₃

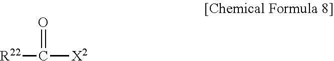

wherein R²² is C1-C5 alkyl; M is B, Al, or Sn; and X¹ and X² are independently of each other halogen.

As a specific example, in Chemical Formulae 6 to 8, R₁ may be C1-C3 alkyl; R² and R³ may be independently of each other C1-C3 alkyl or C1-C3 alkoxy; R²¹ is C1-C3 alkoxy; R²² is C1-C3 alkyl; M is Al; and X¹ and X² may be identically Cl.

In the preparation method, the alkyllithium may be a compound in which lithium is bonded to C1-C5 alkyl, specifically, methyllithium, ethyllithium, or n-butyllithium, preferably n-butyllithium.

In the halogenated metal of Chemical Formula 7, the metal of M may be any one metal selected from Group 13 metals, and preferably, M may be B, Al, or Sn, and the halogen of X¹ and X² may be any one halogen selected from F, Cl, Br, and I. More specifically, M may be Al, and X¹ and X² may be Cl.

According to an exemplary embodiment, all of the reactions may be performed in an organic solvent, specifically one or a mixed organic solvent of two or more selected from hexane, diethyl ether, toluene, tetrahydrofuran, and the like, but is not limited thereto.

In addition, a reaction temperature in all of the reactions may be used at a temperature used in common organic synthesis, but may vary depending on a reaction time, a reaction material, and an amount of starting material.

After the reaction, purity may be increased by removing by-products through filtration, extraction, recrystallization, distillation, sublimation, chromatography, and the like.

Since the aminoalkoxysilylamine compound prepared by the method is thermally stable and highly volatile, it may be used in forming a silicon-containing thin film having good characteristics, and also has excellent reactivity in a broad temperature range, so that the silicon-containing thin film may be stably manufactured.

In addition, the present disclosure provides a composition for depositing a silicon-containing thin film including a compound represented by the following Chemical Formula 11:

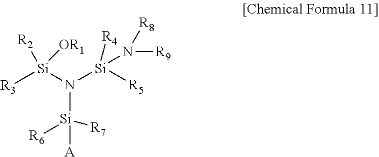

wherein R₁ is C1-C5 alkyl; R₂, R₃, R₆, and R₇ are independently of one another hydrogen, C1-C5 alkyl, or C1-C5 alkoxy; R₄, R₅, and R₈ are independently of one another hydrogen or C1-C5 alkyl; R₉ is C1-C5 alkyl; A is NR₁₀R₁₁ or OR₁₂; R₁₀ is hydrogen or C1-C5 alkyl; and R₁₁ and R₁₂ are independently of each other C1-C5 alkyl.

The aminoalkoxysilylamine compound included in the composition for depositing a silicon-containing thin film of the present disclosure has a structure in which at least one or more alkoxy functional groups and an amine functional group are introduced simultaneously to each silicon atom having a trisilylamine structure, and has improved reactivity with lower activation energy due to the alkoxy functional group introduced to the silicon atom and does not produce nonvolatile by-products, thereby easily forming a high-purity silicon-containing thin film with a high deposition rate.

In addition, since the content of a silicon atom in the molecule is high, the composition for depositing a silicon-containing thin film including the compound may easily deposit a high-quality silicon-containing thin film with a high deposition rate and has high thermal stability, and thus, a thin film having high durability and excellent purity may be manufactured.

The composition for depositing a silicon-containing thin film of the present disclosure may be included within the content range which may be recognized by a person skilled in the art considering film formation conditions or thin film thickness, properties, and the like of the thin film.

In addition, the present disclosure provides a method for manufacturing a silicon-containing thin film using the aminoalkoxysilylamine compound represented by the following Chemical Formula 11:

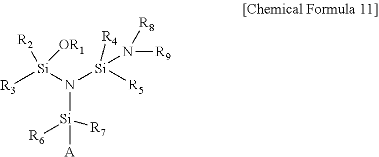

wherein R₁ is C1-C5 alkyl; R₂, R₃, R₆, and R₇ are independently of one another hydrogen, C1-C5 alkyl, or C1-C5 alkoxy; R₄, R₅, and R₈ are independently of one another hydrogen or C1-C5 alkyl; R₉ is C1-C5 alkyl; A is NR₁₀R₁₁ or OR₁₂; R₁₀ is hydrogen or C1-C5 alkyl; and R₁₁ and R₁₂ are independently of each other C1-C5 alkyl.

Specifically, Chemical Formula 11 according to an exemplary embodiment of the present disclosure may be represented by the following Chemical Formula 12 or Chemical 13:

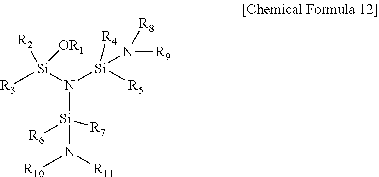

wherein
R₁ is C1-C5 alkyl;
R₂, R₃, R₆, and R₇ are independently of one another hydrogen, C1-C5 alkyl, or C1-C5 alkoxy;
R₄, R₅, R₈, and R₁₀ are independently of one another hydrogen or C1-C5 alkyl; and
R₉ and R₁₁ are C1-C5 alkyl,

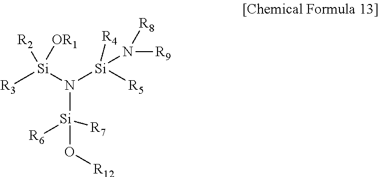

wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl; and
R₉ and R₁₂ are independently of each other C1-C5 alkyl.

In the method for manufacturing a silicon-containing thin film according to a specific example, a thin film is manufactured using a composition for depositing a silicon-containing thin film including the aminoalkoxysilylamine compound which is thermally stable and highly volatile as a precursor, whereby a silicon-containing thin film having excellent characteristics may be manufactured.

The silicon-containing thin film according to a specific example may be any film which may be manufactured within a range which may be recognized by a person skilled in the art, and specifically, may be a silicon oxide film (SiO₂), a silicon oxycarbide film (SiOC), a silicon nitride film (SiN), a silicon oxynitride film (SiON), a silicon carbonitride film (SiCN), a silicon carbide film (SiC), or the like, and various high-quality thin films including silicon within a range which may be recognized by a person skilled in the art may be manufactured.

The method for manufacturing a silicon-containing thin film according to a specific example may be any method allowed within a range which may be recognized by a person skilled in the art, and preferably, may be performed by atomic layer deposition (ALD), chemical vapor deposition (CVD), metalorganic chemical vapor deposition (MOCVD), low pressure chemical vapor deposition (LPCVD), plasma-enhanced chemical vapor deposition (PECVD), or plasma-enhanced atomic layer deposition (PEALD), and plasma-enhanced chemical vapor deposition (PECVD) or plasma-enhanced atomic layer deposition (PEALD) is preferred in terms of easier thin film deposition and excellent properties of a manufactured thin film.

The method for manufacturing a silicon-containing thin film according to a specific example may include, specifically, a) heating a temperature of a substrate mounted in a chamber to 30 to 400 °C and maintaining the temperature; b) bringing the substrate into contact with the aminoalkoxysilylamine compound according to a specific example or the composition for depositing a silicon-containing thin film according to a specific example to adsorb the compound or the composition onto the substrate; and c) injecting a reaction gas to deposit a silicon-containing thin film on the substrate.

Preferably, when depositing the silicon-containing thin film according to a specific example of the present disclosure by plasma-enhanced atomic layer deposition (PEALD) or plasma-enhanced chemical vapor deposition (PECVD), generating plasma may be further included after step a). In addition, in step b), the aminoalkoxysilylamine compound according to a specific example or the composition for depositing a silicon-containing thin film according to a specific example may be injected with a transport gas.

In the method for manufacturing a silicon-containing thin film according to a specific example, deposition conditions may be adjusted depending on the structure or thermal properties of the desired thin film, and as the deposition conditions according to a specific example, an input flow rate of the composition for depositing a silicon-containing thin film containing the aminoalkoxysilylamine compound, an input flow rate of reaction gas and carrier gas, pressure, RF power, a substrate temperature and the like may be exemplified, and as a non-limited example of the deposition condition, the conditions may be adjusted in the following ranges: an input flow rate of the composition for depositing a silicon-containing thin film of 10 to 1000 cc/min, a flow rate of carrier gas of 10 to 1000 cc/min, a flow rate of reaction gas of 1 to 1000 cc/min, a pressure of 0.5 to 10 torr, a RF power of 200 to 1000 W, and a substrate temperature of 30 to 400 °C, preferably 100 to 350 °C, but are not limited thereto.

The reaction gas used in the method for manufacturing a silicon-containing thin film according to a specific example may be any gas which is commonly used with a silicon precursor considering the a material of the silicon-containing thin film to be manufactured, and as a specific example, may be any one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H4), amine, diamine, carbon monoxide (CO), carbon dioxide (CO₂), C1 to C12 saturated or unsaturated hydrocarbon, hydrogen, argon, and helium, and the transport gas may be one or two or more selected from argon, helium, and nitrogen, but the present disclosure is not limited thereto.

The substrate used in the method for r manufacturing a silicone-containing thin film according to a specific example may be a substrate including one or more semiconductor materials of Si, Ge, SiGe, GaP, GaAs, SiC, SiGeC, InAs, and InP; a silicon on insulator (SOI) substrate; a quartz substrate; a glass substrate for display; a flexible plastic substrate such as polyimide, polyethylene terephthalate (PET), polyethylene naphthalate (PEN), polymethyl methacrylate (PMMA), polycarbonate (PC), polyethersulfone (PES), and polyester; and the like, but is not limited thereto.

In addition, in addition to formation of the silicon-containing thin film directly on the substrate, a plurality of conductive layers, dielectric layers, insulating layers, or the like may be formed between the substrate and the silicon-containing thin film.

Hereinafter, the examples of the present disclosure will be described in detail. However, they are provided so that the present disclosure may be easily carried out by those skilled in the art, the present disclosure may be implemented in various forms, and the idea of the present disclosure is not necessarily limited to the examples.

Hereinafter, the structure of the aminoalkoxysilylamine compound according to an exemplary embodiment of the present disclosure was analyzed by ¹H NMR, ¹³C NMR, and ²⁹Si-NMR spectra.

In addition, the thermal stability, volatility, and decomposition temperature of the obtained aminoalkoxysilylamine compound were measured by thermogravimetric analysis (TGA) and differential scanning calorimeter (DSC).

In addition, the thickness of the silicon-containing thin films according to the examples was measured using an ellipsometer (OPTI-PROBE 2600, THERMA-WAVE).

### [Example 1] Synthesis of (bis(dimethylamino)(methylsilyl))(methyldimethoxysilyl)amine

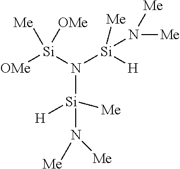 [SMILES: CO[Si](C)(OC)N([SiH](C)N(C)C)[SiH](C)N(C)C]

514 g (2.68 mol) of (bis(dimethylamino)(methylsilyl))amine (C₆H₂₁N₃Si₂) and 1, 753 mL (13.43 mol) of hexane (C₆H₁₄) were added to a flame dried 4,000 mL flask under an anhydrous and inert atmosphere, and 1,049 ml (2.68 mol) of 2.56 M n-butyllithium (C₄H₉Li) was slowly added while maintaining internal temperature at −20 °C. After completing the addition, stirring was performed at normal temperature for 5 hours to prepare a (bis(dimethylamino)(methylsilyl))amine lithium salt (C₆H₂₁N₃Si₂Li). 365.78 g (2.68 mol) of methyltrimethoxysilane (C₄H₁₂O₃Si) and 1,000 mL (11.60 mol) of hexane (C₆H₁₄) were added to a flame dried 5,000 mL flask under an anhydrous and inert atmosphere, a (bis(dimethylamino)(methylsilyl))amine lithium salt (C₆H₂₁N₃Si₂Li) was slowly added while maintaining internal temperature at −20 °C, and stirring was performed at normal temperature for 20 hours. After completing the reaction, the reaction mixture was filtered to remove a methoxylithium salt (LiOCH₃), a solvent was removed from the obtained filtrate under reduced pressure, and distillation under reduced pressure was performed at 72 °C@1 torr to obtain 348 g (1.17 mol) of (bis(dimethylamino)(methylsilyl))(methyldimethoxysilyl)amine which is the title compound (yield: 43.8%).

¹H-NMR (C₆D₆): δ 0.20 (s, 3H Si(CH₃)((OCH₃)₂) 0.34 (m, 6H, (SiHN((CH₃)₂CH₃)₂, 2.49 (d, 12H(Si—N((CH₃)₂)₂, 3.35 (s, 6H, (Si—OCH₃)₂), 4.78 (m, 2H, (Si—H)₂

²⁹Si-NMR (C₆D₆): δ −18.19 (SiH(CH₃)(N((CH₃)₂)₂, −18.60 (Si(CH₃)((OCH₃)₂)

¹³C-NMR (C₆D₆): δ 49.49 (Si(CH₃)((OCH₃)₂), 38.22 (SiH(CH₃)(N((CH₃)₂)₂,

−0.83 (Si(CH₃)((OCH₃)₂), −4.17 (SiH(CH₃)(N((CH₃)₂)₂.

### [Example 2] Synthesis of (bis(dimethylamino)(methylsilyl))(methylmethoxysilyl)amine

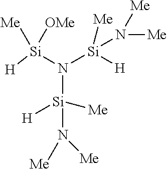 [SMILES: CO[SiH](C)N([SiH](C)N(C)C)[SiH](C)N(C)C]

269 g (1.40 mol) of (bis(dimethylamino)(methylsilyl))amine (C₆H₂₁N₃Si₂) and 917 mL (7.02 mol) of hexane (C₆H₁₄) were added to a flame dried 4,000 mL flask under an anhydrous and inert atmosphere, and 549 ml (1.40 mol) of 2.56 M n-butyllithium (C₄H₉Li) was slowly added while maintaining internal temperature at −20 °C. After completing the addition, stirring was performed at normal temperature for 5 hours to prepare a (bis(dimethylamino)(methylsilyl))amine lithium salt (C₆H₂₁N₃Si₂Li). 149.24 g (1.40 mol) of methyldimethoxysilane (C₃H₁₀O₂Si) and 1,000 mL (11.60 mol) of hexane (C6H14) were added to a flame dried 5,000 mL flask under an anhydrous and inert atmosphere, a (bis(dimethylamino)(methylsilyl))amine lithium salt (C₆H₂₁N₃Si₂Li) was slowly added while maintaining internal temperature at −20 °C, and stirring was performed at normal temperature for 5 hours. After completing the reaction, the reaction mixture was filtered to remove a methoxylithium salt (LiOCH₃), a solvent was removed from the obtained filtrate under reduced pressure, and distillation under reduced pressure was performed at 84 °C@5.4 torr to obtain 180 g (0.677 mol) of (bis(dimethylamino)(methylsilyl))(methylmethoxysilyl)amine which is the title compound (yield: 48.2%).

¹H-NMR (C₆D₆): δ 0.22 (d, 3H Si(CH₃)H((OCH₃)), 0.28 (m, 6H, (SiHN((CH₃)₂CH₃)₂,

2.46 (d, 12H(Si—N((CH₃)₂)₂, 3.36 (s, 3H, (Si(CH₃)H((OCH₃)), 4.57 (m, 3H Si(CH₃)H((OCH₃)), 4.78 (m, 2H, (SiHN((CH₃)₂CH₃)₂

²⁹Si-NMR (C₆D₆): δ −17.43 (SiH(CH₃)(N((CH₃)₂)₂, −31.68 (Si(CH₃)H((OCH₃))

### [Example 3] Synthesis of (bis(dimethylamino)(dimethylsilyl))(methyldimethoxysilyl)amine

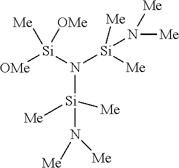 [SMILES: CO[Si](C)(OC)N([Si](C)(C)N(C)C)[Si](C)(C)N(C)C]

50 g (0.36 mol) of methyltrimethoxysilane (C₄H₁₂O₃Si) and 0.1 g (0.005 mol) of aluminum chloride (AlCl₃) were added to a flame dried 250 mL flask under an anhydrous and inert atmosphere, 34.57 g (0.44 mol) of acetyl chloride (CH₃COCl) was slowly added while maintaining internal temperature at normal temperature, and then stirring was performed at 55 °C for 24 hours. After completing the reaction, a reaction mixture was filtered to remove aluminum chloride (AlCl₃), and methyl acetate (CH₃COOCH₃) produced after the reaction was removed from the obtained filtrate under reduced pressure to prepare chlorodimethoxymethylsilane (C₃H₉C₁O₂Si).

30 mL (0.22 mol) of hexane (C₆H₁₄) was added to 10 g (0.045 mol) of bis(dimethylamino)dimethylsilylamine (C₈H₂₅N₃Si₂) and then 17.7 mL (0.045 mol) of 2.56 M n-butyllithium (C₄H₉Li) was slowly added at −20 °C. After stirring at normal temperature for 5 hours, a bis(dimethylamino)dimethylsilylamine lithium salt (C₈H₂₄N₃Si₂Li) was prepared. 30 mL (0.22 mol) of hexane (C₆H₁₄) was added to chlorodimethoxymethylsilane (C₃H₉ClO₂Si) prepared above, a bis(dimethylamino)dimethylsilylamine lithium salt (C₈H₂₄N₃Si₂Li) was slowly added while maintaining internal temperature at −20 °C, and then stirring was performed at normal temperature for 5 hours. After completing the reaction, a reaction mixture was filtered to remove lithium chloride (LiCl), the solvent was removed from the obtained filtrate under reduced pressure, and 9.5 g (0.029 mol) of (bis(dimethylamino)(dimethylsilyl))(methyldimethoxysilyl)amine (CH₃Si(CH₃₀)₂N(Si(CH₃)₂(NCH₃)₂)₂) which is the title compound was obtained (yield: 68%).

¹H-NMR (C₆D₆): δ 0.20 (s, 3H CH₃Si(CH₃O)₂), δ 0.30 (s, 12H N(Si(CH₃)₂N(CH₃)₂)₂), 2.44 (s, 12H N(Si(CH₃)₂N(CH₃)₂)₂), 3.33 (s, 6H CH₃Si(CH₃O)₂)

²⁹Si-NMR (C₆D₆): δ −5.35 (N(Si(CH₃)₂N(CH₃)₂)₂, −27.90 CH₃Si(CH₃O)₂.

### [Example 4] Manufacture of Silicon Oxide Thin Film by Plasma-Enhanced Atomic Layer Deposition (PEALD)

In order to form a silicon oxide thin film in a common plasma-enhanced atomic layer deposition (PEALD) device using known plasma-enhanced atomic layer deposition (PEALD), the aminoalkoxysilylamine compound prepared in Example 3 was used as a precursor and evaluation of silicon oxide film formation was performed.

As a substrate on which the silicon oxide thin film was to be formed, a silicon substrate was used, and the silicon substrate was transferred into a deposition chamber and its temperature was maintained constantly at the temperature described in Table 1.

A bubbler type canister made of stainless steel filled with the precursor was maintained at a temperature described in the following Table 1 so that the vapor pressure of the precursor was constant. The vaporized precursor was transferred into the chamber using an argon gas as a transfer gas, and formed into a film on the silicon substrate.

Specifically, the silicon substrate was maintained at 200 °C, and the precursor of Example 3 was filled into a stainless steel bubbler vessel, which was maintained at 83 °C. As the reaction gas, argon was used together with oxygen, and argon as an inert gas was used for purging. The detailed silicon oxide thin film deposition method is shown in the following Table 1:

TABLE 1
Silicon oxide thin film deposition conditions by plasma-enhanced atomic layer deposition

| | Precursor | | | | | Reaction gas | | | |
|---|---|---|---|---|---|---|---|---|---|
| | heating | Substrate | Precursor | Purge | | and plasma | | Reaction gas purge | |
| | temper- | temper- | injection | Flow | | Flow | RF | | Flow |
| | ature | ature | time | rate | Time | rate | power | Time | rate |
| Precursor | (°C) | (°C) | (sec) | (sccm) | (sec) | (sccm) | (W) | (sec) | (sccm) |
| Example 3 | 63 | 50 to 450 | 0.8 | 600 | 1.0 | 1000 | 500 | 1.5 | 300 |

The thickness of the deposited thin film was measured using an ellipsometer (UV Spectroscopic Ellipsometer, Elli-SEU-am12, Ellipso technology), silicon oxide thin film formation was analyzed using an infrared spectrophotometer (Fourier transform infrared, VERTEX 70v, Bruker), and a silicon oxide thin film composition was analyzed using X-ray photoelectron spectrometer (K-Alpha+, ThermoFisher Scientific). In addition, the step coverage of the silicon oxide thin film was confirmed using a transmission electron microscope (Tecnai F-30 S-Twin, FEI).

### [Comparative Example 1] Manufacture of Silicon Oxide Thin Film by Plasma-Enhanced Atomic Layer Deposition (PEALD)

A silicon oxide thin film was formed in the same manner as in Example 4, except that a diisopropylaminosilane precursor cooled to 11 °C was precursor instead of the aminoalkoxysilylamine compound prepared in Example 3, and the experiment was performed in a temperature range of 50 to 200 °C of the silicon substrate. The thickness of the deposited thin film was measured using an ellipsometer (UV Spectroscopic Ellipsometer, Elli-SEU-am12, Ellipso technology), and the composition of the silicon oxide thin film was analyzed using an X-ray photoelectron spectrometer (K-Alpha+, ThermoFisher Scientific).

### [Comparative Example 2] Manufacture of Silicon Oxide Thin Film by Plasma-Enhanced Atomic Layer Deposition (PEALD)

A silicon oxide thin film was formed in the same manner as in Example 4, except that a bis-tertiarybutylaminosilane precursor heated to 41 °C was used as the precursor instead of the aminoalkoxysilylamine compound prepared in Example 3, and the experiment was performed in a temperature range of 50 to 200 °C of the silicon substrate. The thickness of the deposited thin film was measured using an ellipsometer (UV Spectroscopic Ellipsometer, Elli-SEU-am12, Ellipso technology), and the composition of the silicon oxide thin film was analyzed using an X-ray photoelectron spectrometer (K-Alpha+, ThermoFisher Scientific).

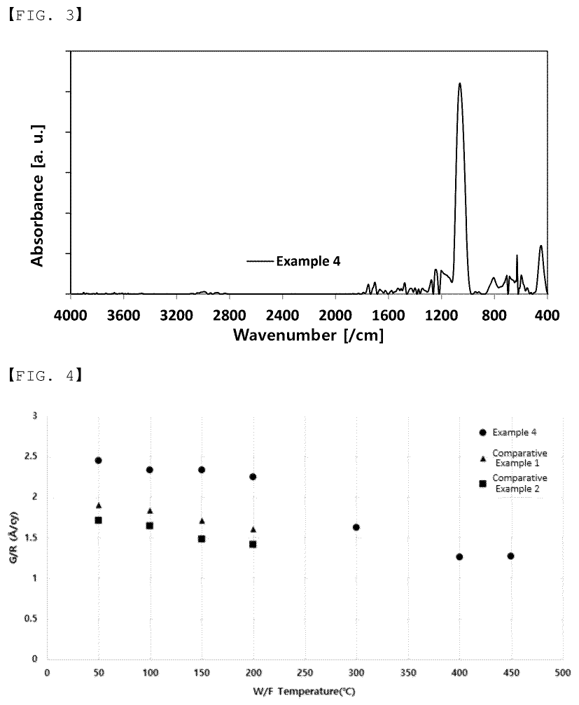

In FIG. 3, a spectrum of analysis results of the thin film deposited in Example 4 by an infrared spectrometer is shown, and it was found that a Si—O bond was exactly shown at a wave number of 1060 cm⁻¹.

FIG. 4 is a graph showing the thickness of the deposited thin film depending on a substrate temperature by ellipsometer analysis of the thin films of Example 4, Comparative Example 1, and Comparative Example 2. The aminoalkoxysilylamine compound precursor of Example 4 was shown to have an atomic layer deposition process section at a silicon substrate temperature of 100 to 200 °C and an atomic layer deposition process section (ALD window) of 400 °C or higher, but in Comparative Examples 1 and 2 using diisopropylaminosilane and the bis-tertiarybutylaminosilane precursor, it was observed that the thickness of the thin film deposited per one cycle was decreased depending on a substrate temperature rise without the atomic layer deposition process temperature range from 50 to 200 °C. In addition, under the same conditions, since Example 4 showed a larger thin film thickness deposited per one cycle than Comparative Examples 1 and 2, the precursor may be a precursor favorable for a process requiring a high throughput.

In addition, the following Table 2 shows results of analyzing the composition of the deposited thin film and impurities using an X-ray photoelectron spectrometer. The thin films deposited in Example 4 and Comparative Examples 1 and 2 were all shown to be thin films having no carbon and nitrogen impurities, and an O/Si ratio at the same silicon substrate temperature at 100 °C was 1.99 in Example 4 meaning that an ideal SiO₂ thin film was formed, but it was 2.04 and 2.08 in Comparative Examples 1 and 2 meaning thin films containing much 0.

TABLE 2
Analysis results of silicon oxide thin film
by X-ray photoelectron spectrometer

| | Substrate | | | | | Atomic |
|---|---|---|---|---|---|---|
| | temperature | Atomic content ratio (%) | | | | ratio |
| | (°C) | Si | O | C | N | O/Si |
| Example 4 | 50 | 33.2 | 66.8 | 0.0 | 0.0 | 2.01 |
| Example 4 | 100 | 33.4 | 66.6 | 0.0 | 0.0 | 1.99 |
| Example 4 | 400 | 33.7 | 66.3 | 0.0 | 0.0 | 1.97 |
| Comparative | 100 | 32.9 | 67.1 | 0.0 | 0.0 | 2.04 |
| Example 1 | | | | | | |
| Comparative | 100 | 32.4 | 67.6 | 0.0 | 0.0 | 2.08 |
| Example 2 | | | | | | |

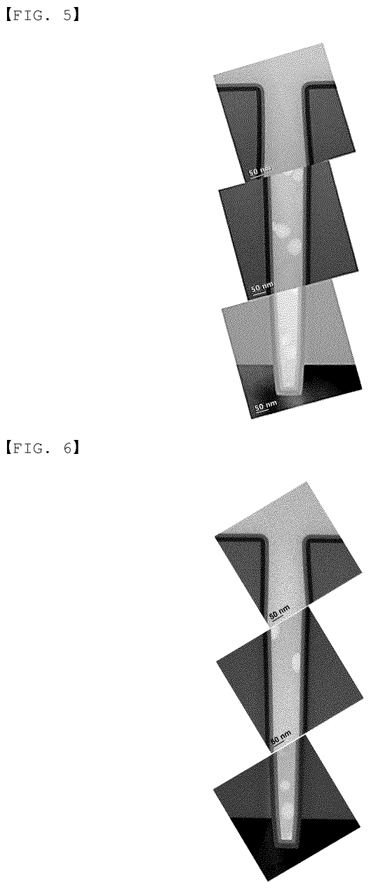

In FIGS. 5 and 6, results of performing transmission electron microscopy analysis for observing the step coverage of the thin film manufactured at substrate temperatures of 200 °C and 400 °C of Example 4 are shown. The step coverage was shown to be excellent at 101% and 97% based on the lower wall surface in the pattern substrate having an aspect ratio of 14.

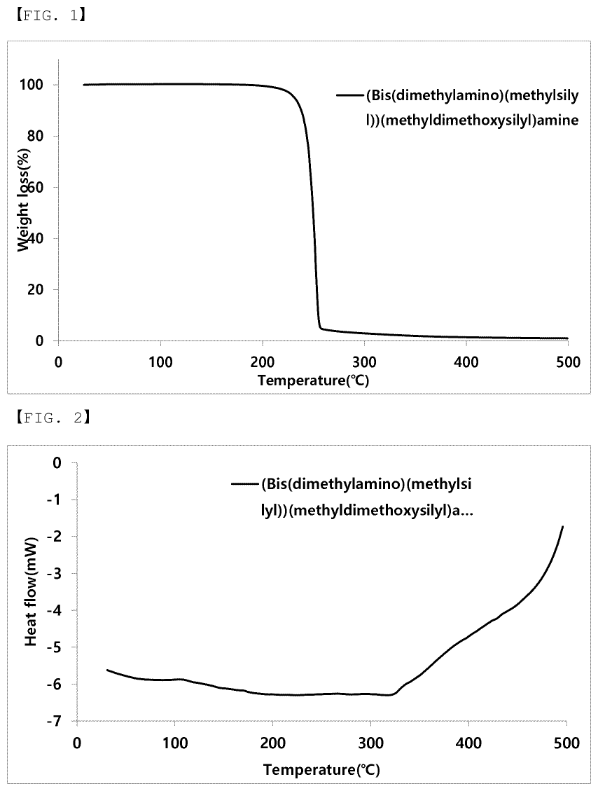

From FIGS. 1 and 2, the high volatility, stability, and thermal decomposition properties of the aminoalkoxysilylamine compound precursors prepared in Examples 1 to 3 were confirmed.

In addition, from Table 2 and FIGS. 3, 4, 5, and 6, it was found that the aminoalkoxysilylamine compound according to an exemplary embodiment of the present disclosure may be used as a precursor for thin film deposition to produce a silicon-containing thin film having excellent characteristics with a high throughput, and the manufactured silicon-containing thin film had excellent step coverage properties.

The present disclosure has been described in detail in specific parts, and it is obvious that such specific technique is only a non-limiting embodiment to a person skilled in the art, without limiting the scope of the present disclosure. Thus, the substantial scope of the present disclosure will be defined by the appended claims and their equivalents.

1. An aminoalkoxysilylamine compound represented by the following Chemical Formula 1: 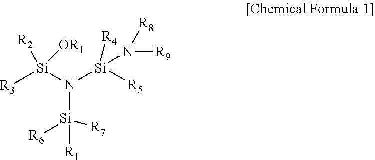
wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl;
with the proviso that cases in which A is OR₁₂, R₁, R₈, R₉, and R₁₂ are all ethyl, and R₂ to R₇ are all methyl are excluded.

2. The aminoalkoxysilylamine compound of claim 1,
wherein R¹ is C1-C3 alkyl;
R₂, R₃, R₆, and R₇ are independently of one another hydrogen, C1-C3 alkyl, or C1-C3 alkoxy;
R₄, R₅, and R₈ are independently of one another hydrogen or C1-C3 alkyl;
R₉ is C1-C3 alkyl;
A is NR₁₀R₁₁ or OR₁₂;
R₁₀ is hydrogen or C1-C3 alkyl; and
R₁₁ and R₁₂ are independently of each other C1-C5 alkyl;
with the proviso that cases in which A is OR₁₂, and R₁, R₈, R₉, and R₁₂ are all ethyl are excluded.

3. The aminoalkoxysilylamine compound of claim 1, wherein the aminoalkoxysilylamine compound is represented by the following Chemical Formula 2 or 3: 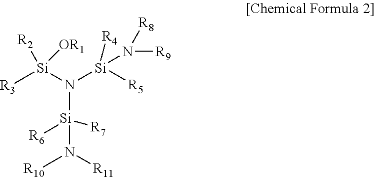
wherein
R₁ is C1-C5 alkyl;
R₂, R₃, R₆, and R₇ are independently of one another hydrogen, C1-C5 alkyl, or C1-C5 alkoxy;
R₄, R₅, R₈, and R₁₀ are independently of one another hydrogen or C1-C5 alkyl; and
R₉ and R₁₁ are C1-C5 alkyl, 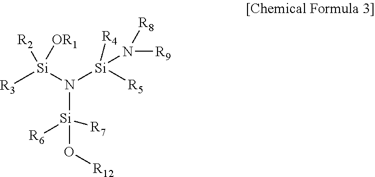
wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl; and
R₇ and R₁₂ are independently of each other C1-C5 alkyl;
with the proviso that cases in which R₁, R₈, R₉, and R₁₂ are all ethyl and R₂ to R₇ are all methyl are excluded.

4. The aminoalkoxysilylamine compound of claim 3,
wherein R₁ is C1-C3 alkyl;
R₂, R₃, R₆, and R₇ are independently of one another hydrogen, C1-C3 alkyl, or C1-C3 alkoxy;
R₄, R₅, R₈, and R₁₀ are independently of one another hydrogen or C1-C3 alkyl; and
R₉, R₁₁ and R₁₂ are independently of one another C1-C3 alkyl.

5. The aminoalkoxysilylamine compound of claim 1, wherein the aminoalkoxysilylamine compound is selected from the following compounds:

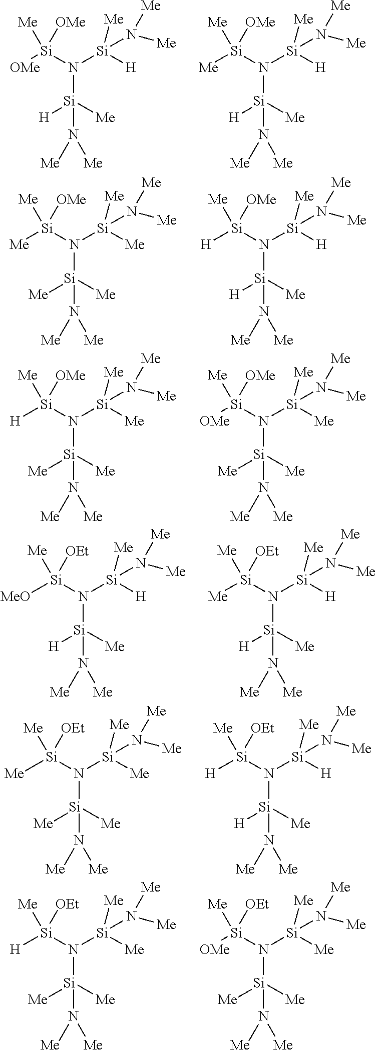

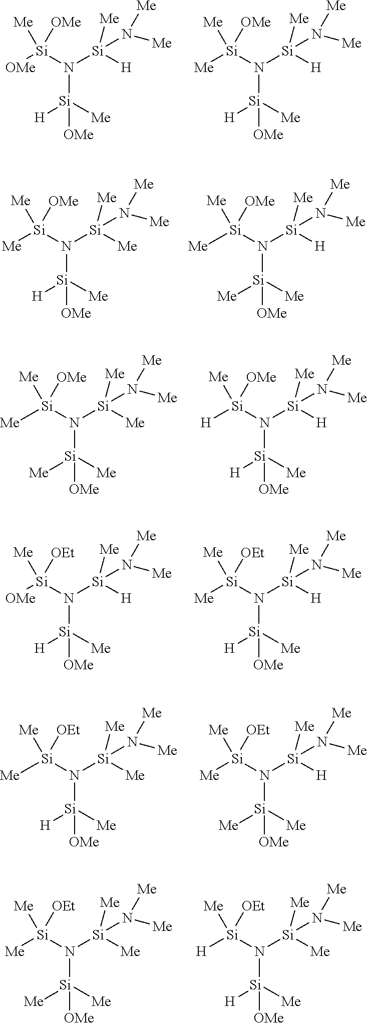

6. A method for preparing an aminoalkoxysilylamine compound of the following Chemical Formula 1, the method comprising: reacting (C1-C5)alkyllithium, a compound of the following Chemical Formula 4, and a compound of the following Chemical Formula 5 to prepare an aminoalkoxysilylamine compound of the following Chemical Formula 1: 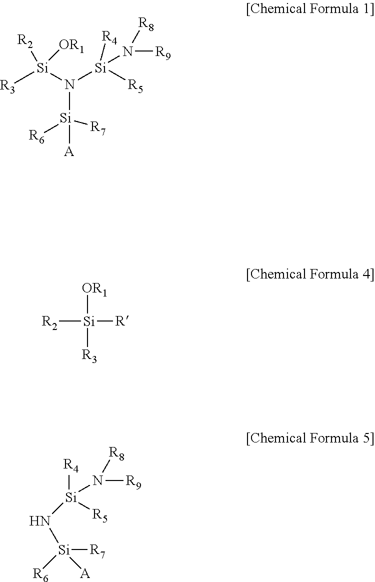
wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
R′ is C1-C5 alkoxy or halogen;
A is NR₁₀R₁₁ or OR₁₂;
R₁₀ is hydrogen or C1-C5 alkyl; and
R₁₁ and R₁₂ are independently of each other C1-C5 alkyl;
with the proviso that cases in which A is OR₁₂, R₁, R₈, R₉, and R₁₂ are all ethyl, and R₂ to R₇ are all methyl are excluded.

7. The method for preparing an aminoalkoxysilylamine compound of claim 6, wherein when R′ is halogen in Chemical Formula 4, reacting a compound of the following Chemical Formula 6 with a halogen source to prepare the compound of Chemical Formula 4 is included: 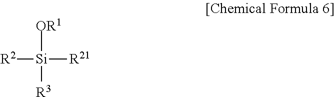
wherein
R₁ is C1-C5 alkyl;
R₂ and R₃ are independently of each other hydrogen, C1-C5 alkyl, or C1-C5 alkoxy; and
R₂₁ is C1-C5 alkoxy.

8. A composition for depositing a silicon-containing thin film comprising an aminoalkoxysilylamine compound represented by the following Chemical Formula 11: 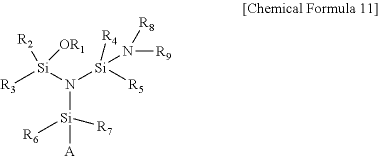
wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl.

9. A method for manufacturing a silicon-containing thin film using an aminoalkoxysilylamine compound represented by the following Chemical Formula 11: 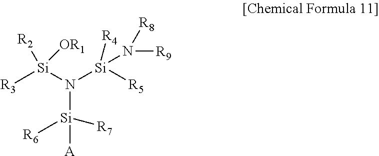
wherein
R₁ is C1-C5 alkyl;
R₂, R₃, R₆, and R₇ are independently of one another hydrogen, C1-C5 alkyl, or C1-C5 alkoxy;
R₄, R₅, and R₈ are independently of one another hydrogen or C1-C5 alkyl;
R₉ is C1-C5 alkyl;
A is NR₁₀R₁₁ or OR₁₂;
R₁₀ is hydrogen or C1-C5 alkyl; and
R₁₁ and R₁₂ are independently of each other C1-C5 alkyl.
